(19) United States
(12) Patent Application Publication
(10) Pub. No.: US 2025/0393334 A1
(43) Pub. Date: Dec. 25, 2025

(54) STRUCTURE AND MANUFACTURING METHOD FOR PHOTO COUPLER SINGLE CHIP

(71) Applicant: Taiwan-Asia Semiconductor Corporation, Hsinchu City (TW)

(72) Inventors: Kun-Li Lin, Hsinchu City (TW); Chuan-Wei Chen, Hsinchu City (TW); Yu-Tong Hsiao, Hsinchu City (TW); Huang-Ming Chen, Hsinchu City (TW)

(21) Appl. No.: 19/029,072

(22) Filed: Jan. 17, 2025

(30) Foreign Application Priority Data
Jun. 20, 2024 (TW) 113122938

(51) Int. Cl. H10F 55/25; H01L 23/00; H10F 30/20; H10F 71/00; H10H 20/01; H10H 20/812

(52) U.S. Cl. CPC H10F 55/25; H01L 24/80; H10F 71/00; H10H 20/011; H01L 2224/08145; H10F 30/20; H10H 20/812

(57) ABSTRACT

A photo coupler single chip structure and a manufacturing method thereof are provided. The photo coupler single chip structure includes a light-emitting unit, a light-receiving unit and an electrical insulation layer. The electrical insulation layer physically connects the light-emitting unit and the light-receiving unit to two opposite sides of the electrical insulation layer. The light-emitting unit can form an optical signal in response to an input signal. The light-receiving unit will directly absorb the optical signal through the electrical insulating layer and convert it into an output signal.

### CROSS-REFERENCES TO RELATED APPLICATIONS

This application claims the benefit of priority to Taiwanese Patent Application No. 113122938 filed on Jun. 20, 2024, which is hereby incorporated by reference in its entirety.

### BACKGROUND OF THE INVENTION

### Field of the Invention

The present invention relates to a photo coupler device and a manufacturing method thereof, in particular to a photo coupler single chip structure having both a light-emitting unit and a light-receiving unit on a single chip and a manufacturing method thereof.

### Descriptions of the Related Art

A photo coupler device is an electronic device that uses light to transmit electrical signals. It typically comprises two chips with different functions: a light-emitting diode (LED) and a light detection unit, such as a phototransistor or photodiode for achieving electrical insulation and signal transmission. This design ensures no direct electrical connection between the input and output circuits. Consequently, it provides high voltage insulation and noise suppression.

As shown in FIG. 1, conventional photo coupler devices can generally be classified into horizontally and vertically arranged packaging structures. In the horizontally arranged packaging structure of the photo coupler device 1, the LED 10 and the light detection unit 20 are disposed opposite each other on the left and right sides inside the photo coupler device 1. In the vertically arranged packaging structure of the photo coupler device 1, the LED 10 and the light detection unit 20 are disposed opposite each other on the top and bottom inside the photo coupler device 1. However, regardless of whether the structure is horizontally or vertically arranged in the photo coupler device 1, the LED 10 and the light detection unit 20 are separate and independent chips. On the path of optical signal transmission, the optical signal generated by the LED 10 must pass through the air or the encapsulating medium outside the LED 10 before being received by the light detection unit 20, resulting in a significant loss in the external quantum efficiency of the LED.

Additionally, in view of the arrangement of physical structures, these two independent chips, the LED 10 and the light detection unit 20, must be separately mounted onto the lead frame 30 to form the final device. Therefore, conventional photo coupler device require space to arrange two independent chips and the lead frame, occupying a substantial volume once assembled. Moreover, the manufacturing process is complex and costly. These issues, such as the light signal transmission path, excessive device volume, and high manufacturing costs, need urgent improvement for the conventional photo coupler devices.

### SUMMARY OF THE INVENTION

The main objective of the present invention is to provide an innovative photo coupler single chip structure and the manufacturing method thereof. The present invention can not only increase the external quantum efficiency of the light-emitting diode, but also reduce the overall volume of the photo coupler device to achieve thinner package and reduce process time and cost.

To achieve the above objective, the present invention discloses a photo coupler single chip structure and a manufacturing method thereof. The photo coupler single chip structure includes a light-emitting unit, a light-receiving unit and an electrical insulation layer. The electrical insulation layer physically connects the light-emitting unit and the light-receiving unit to two opposite sides of the electrical insulation layer. The light-emitting unit can form an optical signal in response to an input signal. The light-receiving unit will directly absorb the optical signal through the electrical insulating layer and convert it into an output signal.

In one embodiment of the photo coupler single chip structure of the present invention, the electrical insulation layer is one of an oxide, a nitride and a transparent colloid.

In one embodiment of the photo coupler single chip structure of the present invention, the oxide comprises aluminum oxide (Al₂O₃) and silicon dioxide (SiO₂).

In one embodiment of the photo coupler single chip structure of the present invention, the nitride comprises silicon nitride.

In one embodiment of the photo coupler single chip structure of the present invention, the transparent colloid is benzocyclobutene (BCB).

In one embodiment of the photo coupler single chip structure of the present invention, the light-receiving unit has a pair of positive and negative electrodes, penetrating the light-emitting unit and electrically connecting to the light-receiving unit.

In one embodiment of the photo coupler single chip structure of the present invention, the light-emitting unit is a single chip structure made by metal-organic chemical vapor deposition.

In one embodiment of the photo coupler single chip structure of the present invention, the light-receiving unit is a silicon PN junction diode.

In addition, the present invention further disclosed a manufacturing method of a photo coupler single chip structure which comprises the following steps. First, a light-emitting unit is provided. Then, a light-receiving unit is provided. A first electrical insulation layer is formed on one side of the light-emitting unit and a second electrical insulation layer is respectively formed on one side of the light-receiving unit. Finally, the first electrical insulation layer and the second electrical insulation layer are bonded to physically connect the light-emitting unit and the light-receiving unit through two opposite sides of the first electrical insulation layer and the second electrical insulation layer, wherein the light-emitting unit can form an optical signal in corresponding to an input signal, and the light-receiving unit will directly absorb the optical signal through the first electrical insulation layer and the second electrical insulation layer and convert it into an output signal.

In one embodiment of the manufacturing method of the present invention, the step of forming the first electrical insulation layer and the second electrical insulation layer comprises a step of respectively forming an oxide both on the light-emitting unit and the light-receiving unit.

In one embodiment of the manufacturing method of the present invention, the step of respectively forming the oxide on the light-emitting unit and the light-receiving unit comprises a step of respectively forming aluminum oxide (Al₂O₃) and silicon dioxide (SiO₂) on the light-emitting unit and the light-receiving unit.

In one embodiment of the manufacturing method of the present invention, the method further comprises a step of forming a pair of positive and negative electrodes, penetrating the light-emitting unit and electrically connecting to the light-receiving unit.

In one embodiment of the manufacturing method of the present invention, the step of providing the light-emitting unit is a step of forming a single chip structure made by metal-organic chemical vapor deposition.

In one embodiment of the manufacturing method of the present invention, the step of providing the light-receiving unit is a step of forming a silicon PN junction diode.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a cross-sectional schematic diagram of two conventional photo coupler devices;

FIG. 2 to FIG. 7 are cross-sectional schematic diagrams illustrating the manufacturing process of the photo coupler single chip structure according to the present invention;

FIG. 8 is a cross-sectional schematic diagram of the photo coupler single chip structure according to the present invention; and

FIG. 9 is a schematic diagram of the process steps for manufacturing the photo coupler single chip structure according to the present invention.

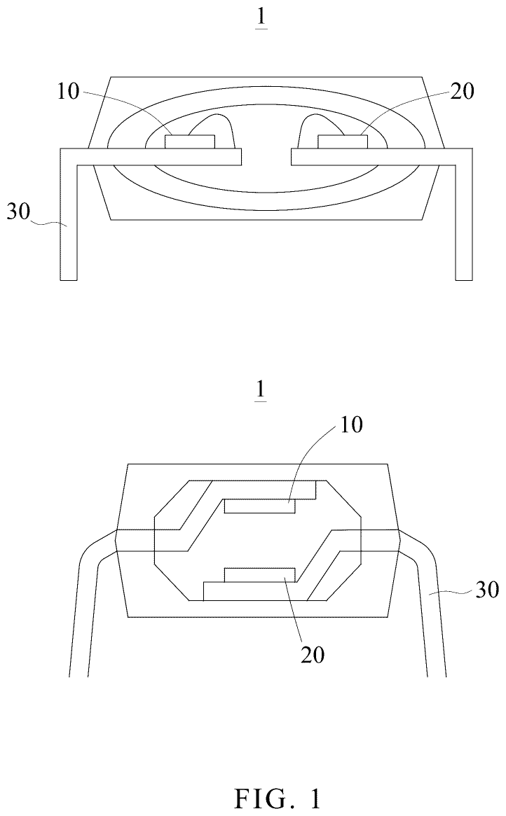

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

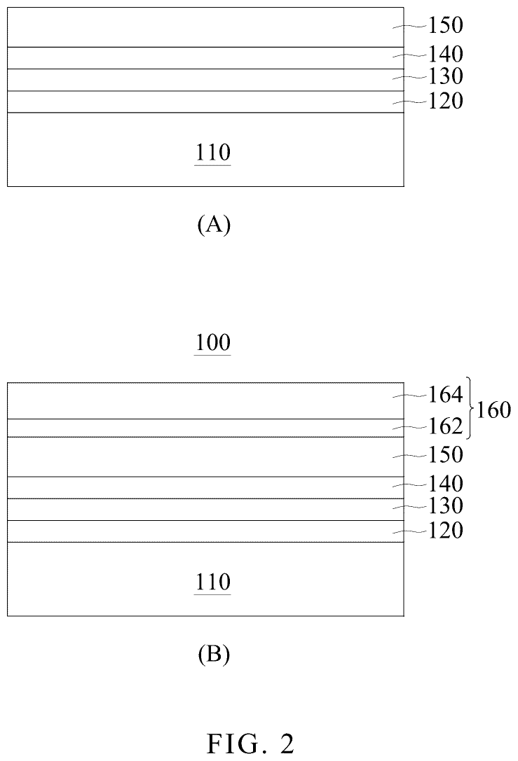

The present invention discloses a photo coupler single chip structure and a manufacturing method thereof. Referring to FIG. 2(A), a wafer is first provided. This wafer can be a gallium arsenide (GaAs) wafer, but is not limited thereto, for forming multiple light-emitting units 100. The light-emitting unit 100 can be a light-emitting diode (LED). In a specific embodiment, the LED has a substrate 110, which is a GaAs substrate. On the substrate 110, a III-V group epitaxial composite layer with a single crystal structure is formed by metal-organic chemical vapor deposition (MOCVD). This epitaxial composite layer sequentially comprises an N-type doped epitaxial layer 120, a multiple quantum well (MQW) 130, a P-type doped epitaxial layer 140, and a gallium phosphide (GaP) epitaxial layer 150. The N-type doped epitaxial layer 120, the MQW 130, and the P-type doped epitaxial layer 140 of the epitaxial composite layer are primarily made by aluminum gallium arsenide (AlGaAs) ternary material. Next, referring to FIG. 2(B), an electrical insulation layer 160 is formed on the light-emitting unit 100. The electrical insulation layer 160 can be one of an oxide, a nitride, and a transparent colloid. In a preferred embodiment, when the electrical insulation layer 160 is selected as an oxide, it may comprise an aluminum oxide (Al₂O₃) layer 162 and a silicon dioxide (SiO₂) layer 164. The aluminum oxide layer 162 is formed on the GaP epitaxial layer 150, and the silicon dioxide layer 164 is formed on the aluminum oxide layer 162. Additionally, when the electrical insulation layer is selected as a nitride, it can include silicon nitride (SiN). On the other hand, when the electrical insulation layer is selected as a transparent colloid, it can include benzocyclobutene (BCB).

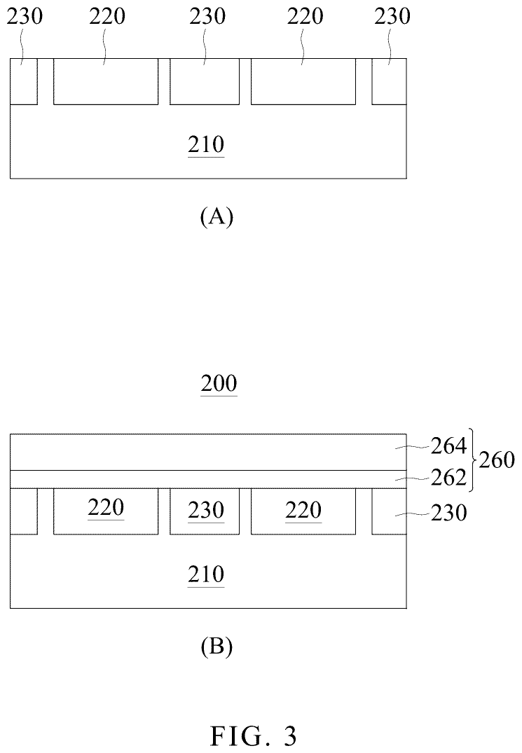

Referring to FIG. 3(A), another wafer is provided next. This wafer can be a silicon wafer for forming multiple light-receiving units 200. The light-receiving unit 200 can be a photodiode, such as a silicon PN junction diode. In a specific embodiment, the photodiode has a substrate 210, which can be an N-type lightly doped silicon (Si) substrate, but is not limited thereto. Next, several P-type heavily doped regions 220 and N-type heavily doped regions 230 are respectively formed and alternatively arranged on the substrate 210 by diffusion or ion implantation to form the PN junction of the photodiode. Then, referring to FIG. 3(B), similar to FIG. 2(B), an electrical insulation layer 260 is formed on the surface of the PN junction of the light-receiving unit 200. The electrical insulation layer 260 can be one of an oxide, a nitride, and a transparent colloid. This electrical insulation layer 260 is the same as the aforementioned electrical insulation layer 160 and will not be redundantly described here. In a preferred embodiment, the electrical insulation layer 260 may comprise an aluminum oxide (Al₂O₃) layer 262 and a silicon dioxide (SiO₂) layer 264. The aluminum oxide layer 262 is formed on the surface of the PN junction of the light-receiving unit 200, and the silicon dioxide layer 264 is formed on the aluminum oxide layer 262.

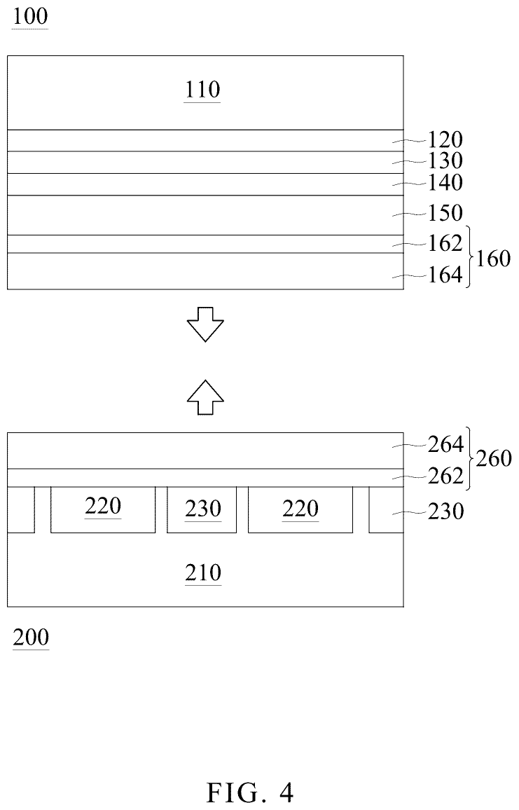

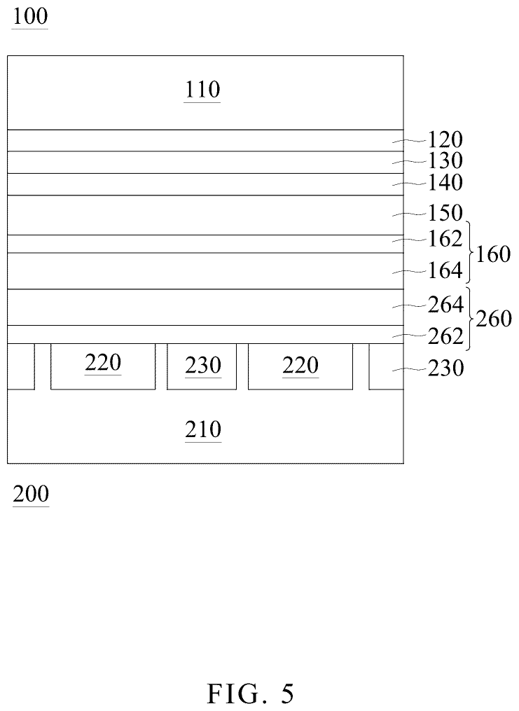

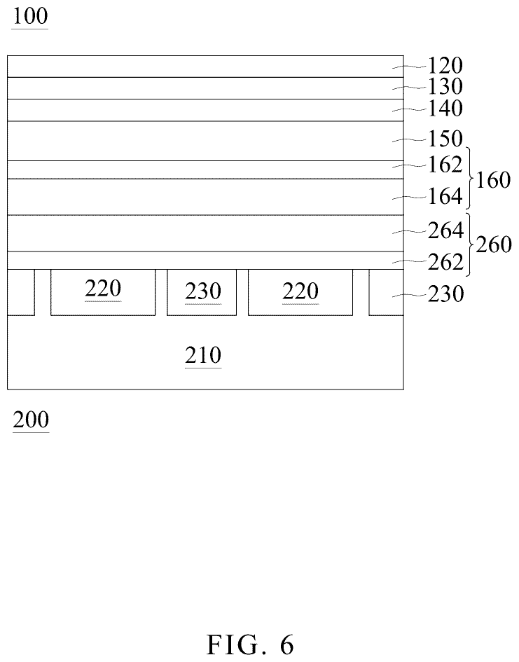

After forming the electrical insulation layers 160 and 260 on the surfaces of the light-emitting unit 100 and the light-receiving unit 200, respectively, in this embodiment, aluminum oxide layers 162 and 262 and silicon dioxide layers 164 and 264 are formed. Then, the silicon dioxide layer 164 on the gallium arsenide wafer with multiple light-emitting units 100 and the silicon dioxide layer 264 on the silicon wafer with multiple light-receiving units 200 are polished using a chemical mechanical polishing (CMP) method. After surface activation, the activated silicon dioxide layer 164 on the gallium arsenide wafer and the activated silicon dioxide layer 264 on the silicon wafer are aligned and bonded together. Under high temperature and high pressure, the oxide layers will adhere to each other, as shown in FIGS. 4 and 5. It is clearly shown in the figures that, after bonding through the two electrical insulation layers 160 and 260, the light-emitting unit 100 is physically connected to the light-receiving unit 200 through two opposite sides of the electrical insulation layers 160 and 260. In a preferred embodiment, the total thickness of the bonded electrical insulation layers 160 and 260 should preferably be not less than 1 micron, and this thickness can be adjusted according to the voltage resistance requirements of the photo coupler device. Next, the gallium arsenide substrate 110, originally used for growing epitaxial layers, is removed using a chemical solution and only the epitaxial composite layer is remained, which includes the N-doped epitaxial layer 120, the multiple quantum well 130, the P-doped epitaxial layer 140, and the gallium phosphide epitaxial layer 150. Thus, a single structure having both the light-emitting unit 100 and the light-receiving unit 200 on one wafer is formed, as shown in FIG. 6.

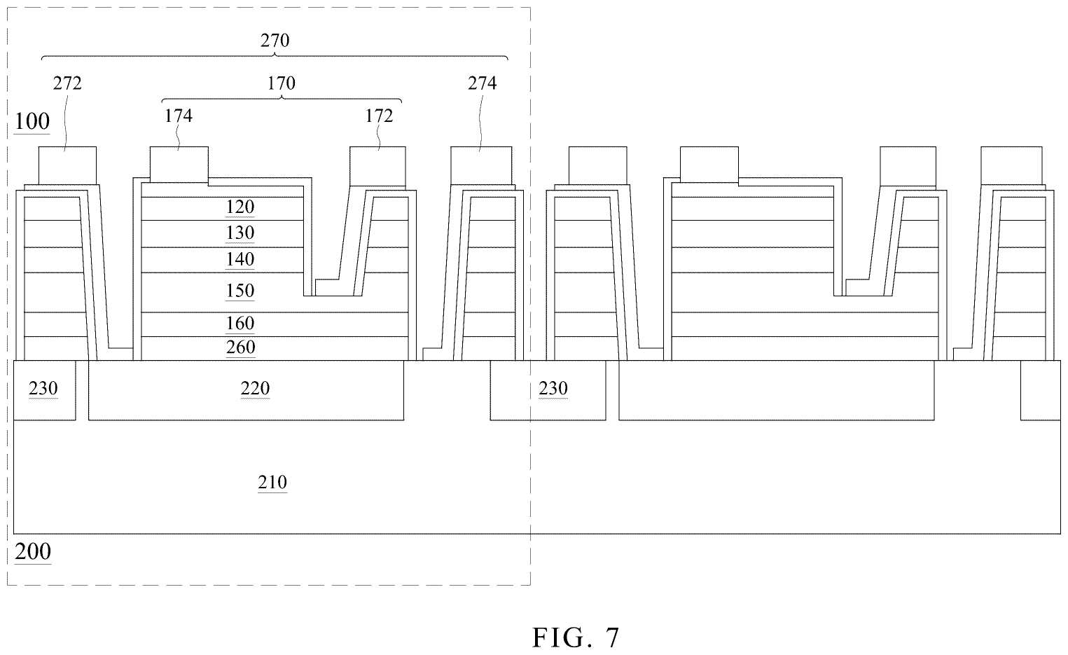

Please refer to FIG. 7, which illustrates a photo coupler single chip will be mainly completed after the following semiconductor processes on the wafer existing the light-emitting unit 100 and the light-receiving unit 200, such as mesa etching for device isolation, chemical vapor deposition, and electrode evaporation. It is noted that a pair of positive and negative electrodes 170 (including a positive electrode 172 and a negative electrode 174) of the light-emitting unit 100 and a pair of positive and negative electrodes 270 (including a positive electrode 272 and a negative electrode 274) of the light-receiving unit 200 are disposed on one side of the light-emitting unit 100 according to the electrode design of the photo coupler single chip. The positive and negative electrodes 170 and 270 are individually electrically connected to the light-emitting unit 100 and the light-receiving unit 200, respectively. For example, when fabricating the positive and negative electrodes 270 of the light-receiving unit 200, a patterned etching process is first performed to etch part of the epitaxial layers of the light-emitting unit 100 to expose part of the light-receiving unit 200, followed by an electrode evaporation process for allowing the positive and negative electrodes 270 to penetrate through the light-emitting unit 100 and electrically connect to the light-receiving unit 200. Moreover, this electrode layout design can be adapted to requirements of the devices as being designed as either wire bonding electrodes or flip chip electrodes to achieve further miniaturization. In a preferred embodiment, the area (not shown) of the negative electrode 174 of the light-emitting unit 100 covering the surface of the device can be increased to reflect the light that would otherwise escape from the light-emitting unit 100 back into the device so as to enhance the efficiency of the device.

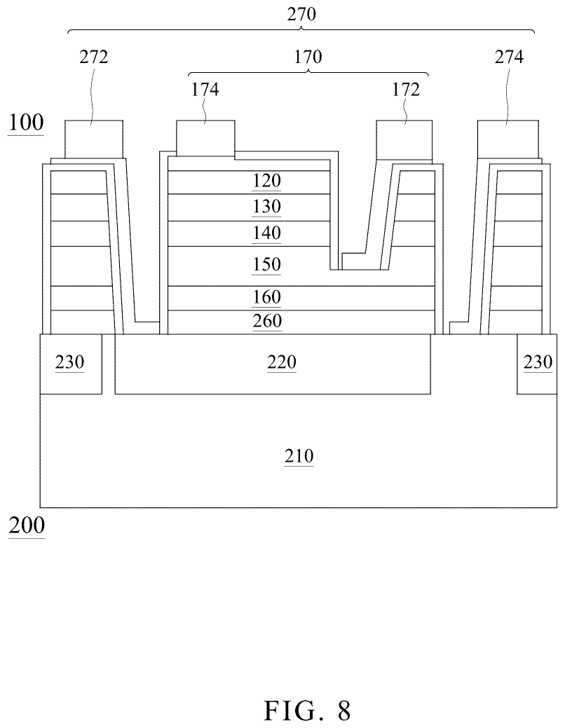

Finally, after performing the wafer dicing process, a photo coupler single chip structure that has the light-emitting unit 100 and the light-receiving unit 200 on a single structure can be formed, as shown in FIG. 8. This structure clearly demonstrates that in a single chip, the light emitted from the epitaxial layer of the light-emitting diode passes directly through the electrical insulation layer and is absorbed by the light-receiving unit so the external quantum efficiency of the light-emitting diode would be significantly improved. In other words, in the photo coupler single chip device of the present invention, the light-emitting unit can form an optical signal in response to an external input signal, and this optical signal passes through the electrical insulation layer and finally is converted into an output signal after being directly absorbed by the light-receiving unit in the photo coupler single chip device. In this way, the problem of traditional photo coupler devices where the light transmission path must pass through the outside of the light-emitting unit before being received by the light-receiving unit for reducing light efficiency has been overcome. Additionally, the volume of the single-chip structure is significantly reduced for allowing the device to meet further miniaturization requirements while also reducing process time and manufacturing costs.

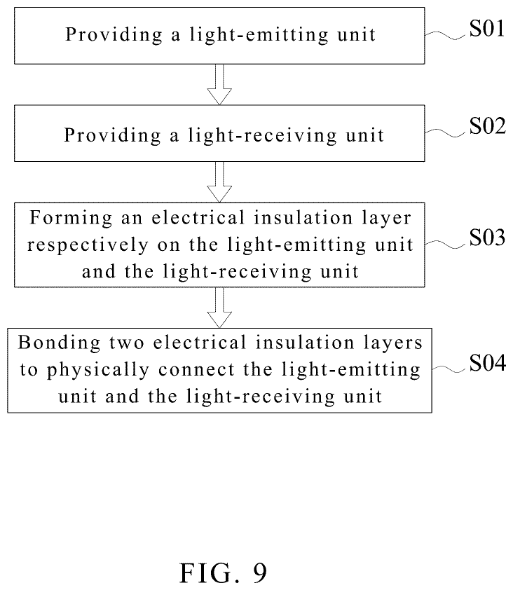

Refer to FIG. 9, which illustrates the step-by-step flowchart for manufacturing the photo coupler single chip structure of the present invention. First, in step S01, a light-emitting unit is provided, which can be a light-emitting diode. Next, in step S02, a light-receiving unit is provided. Then, in step S03, an electrical insulation layer is respectively formed on one side of the light-emitting unit and one side of the light-receiving unit. In step S04, the two electrical insulation layers are bonded to physically connect the light-emitting unit and the light-receiving unit to the two opposite sides of the electrical insulation layers. Thereby, a single structure with both the light-emitting unit and the light-receiving unit is formed. The detailed description of each unit can be referred to in the previous content and is not repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A photo coupler single chip structure, comprising:
a light-emitting unit;
a light-receiving unit; and
an electrical insulation layer, physically connecting the light-emitting unit and the light-receiving unit to two opposite sides of the electrical insulation layer,
wherein the light-emitting unit forms an optical signal in response to an input signal, and the light-receiving unit directly absorbs the optical signal through the electrical insulating layer and convert it into an output signal.

2. The photo coupler single chip structure of claim 1, wherein the electrical insulation layer is one of an oxide, a nitride and a transparent colloid.

3. The photo coupler single chip structure of claim 2, wherein the oxide comprises aluminum oxide (Al₂O₃) and silicon dioxide (SiO₂).

4. The photo coupler single chip structure of claim 2, wherein the nitride comprises silicon nitride.

5. The photo coupler single chip structure of claim 2, wherein the transparent colloid is benzocyclobutene (BCB).

6. The photo coupler single chip structure of claim 1, wherein the light-receiving unit has a pair of positive and negative electrodes, penetrating the light-emitting unit and electrically connecting to the light-receiving unit.

7. The photo coupler single chip structure of claim 1, wherein the light-emitting unit is a single chip structure made by metal-organic chemical vapor deposition.

8. The photo coupler single chip structure of claim 1, wherein the light-receiving unit is a silicon PN junction diode.

9. A manufacturing method of a photo coupler single chip structure, comprising:
providing a light-emitting unit;
providing a light-receiving unit; and
respectively forming a first electrical insulation layer on one side of the light-emitting unit and a second electrical insulation layer on one side of the light-receiving unit;
bonding the first electrical insulation layer and the second electrical insulation layer to physically connecting the light-emitting unit and the light-receiving unit to two opposite sides of the first electrical insulation layer and the second electrical insulation layer,
wherein the light-emitting unit forms an optical signal in corresponding to an input signal, and the light-receiving unit directly absorbs the optical signal through the first electrical insulation layer and the second electrical insulation layer and convert it into an output signal.

10. The manufacturing method of claim 9, wherein the step of forming the first electrical insulation layer and the second electrical insulation layer comprises a step of respectively forming an oxide both on the light-emitting unit and the light-receiving unit.

11. The manufacturing method of claim 10, wherein the step of respectively forming the oxide on the light-emitting unit and the light-receiving unit comprises a step of respectively forming aluminum oxide (Al₂O₃) and silicon dioxide (SiO₂) on the light-emitting unit and the light-receiving unit.

12. The manufacturing method of claim 9, further comprising a step of forming a pair of positive and negative electrodes, penetrating the light-emitting unit and electrically connecting to the light-receiving unit.

13. The manufacturing method of claim 9, wherein the step of providing the light-emitting unit is a step of forming a single chip structure made by metal-organic chemical vapor deposition.

14. The manufacturing method of claim 9, wherein the step of providing the light-receiving unit is a step of forming a silicon PN junction diode.
